(19) United States
(12) Patent Application Publication
(10) Pub. No.: US 2026/0149446 A1
(43) Pub. Date: May 28, 2026

(54) INTEGRATED CIRCUIT AND ASSOCIATED REVERSE POLARITY PROTECTION CIRCUIT

(71) Applicant: Chengdu Monolithic Power Systems Co., Ltd., Chengdu (CN)

(72) Inventors: Xiangyi Yang, Chengdu (CN); Zhuoyi Zhao, Chengdu (CN)

(21) Appl. No.: 19/399,918

(22) Filed: Nov. 25, 2025

(30) Foreign Application Priority Data
Nov. 25, 2024 (CN) 202411688981.3

(51) Int. Cl. H03K 17/082; H03K 17/06; H03K 17/30; H03K 17/687

(52) U.S. Cl. CPC H03K 17/0822; H03K 17/063; H03K 17/6871; H03K 17/302; H03K 2217/0081

(57) ABSTRACT

An integrated circuit has an input terminal to receive an input voltage, an output terminal coupled to an output voltage, a reference terminal, a power ground terminal, a power transistor for providing a current conduction path between the input terminal and the output terminal, a main control circuit for providing a control signal relative to the reference terminal to a control electrode of the power transistor, a variable resistance circuit coupled between the reference terminal and the power ground terminal for being switched between an ON state and an OFF state based on a driving voltage applied to a control terminal of the variable resistance circuit, and a driver circuit for adjusting the driving voltage based on the polarity of the input voltage or the polarity of the output voltage.

### CROSS-REFERENCE TO RELATED APPLICATIONS

This application claims the benefit of CN application 202411688981.3, filed on Nov. 25, 2024, and incorporated herein by reference.

### TECHNICAL FIELD

The present invention generally relates to electronic circuits, and more particularly but not exclusively, to integrated circuits with a dedicated reference terminal and associated reverse polarity protection technology.

### BACKGROUND

Electronic devices that receive DC power, especially when it comes to electronic devices in the automotive and industrial applications, generally require protective devices in their power supply path for reverse polarity, i.e. withstand negative voltage on both input terminal and output terminal without being destroyed by some dangerous situations such as fire due to reverse polarity.

### SUMMARY

An embodiment of the present invention discloses an integrated circuit, the integrated circuit comprises an input terminal, an output terminal, a reference terminal, a power ground terminal, a power transistor, a main control circuit, a variable resistance circuit, and a driver circuit. The input terminal is configured to receive an input voltage of a positive polarity or a negative polarity. The output terminal is configured to be coupled to an output voltage of a positive polarity or a negative polarity. The power transistor is configured to provide a current conduction path between the input terminal and the output terminal, and the power transistor has a control electrode. The main control circuit is coupled to the reference terminal and is configured to provide a control signal relative to a voltage level at the reference terminal to the control electrode of the power transistor. The driver circuit is configured to adjust the driving voltage based on the polarity of the input voltage or the polarity of the output voltage.

Another embodiment of the present invention discloses an electronic circuit. The electronic circuit comprises an integrated circuit, an input capacitor and an output capacitor. The integrated circuit comprises an input terminal, an output terminal, a reference terminal, a power ground terminal, a power transistor, a main control circuit, a variable resistance circuit and a driver circuit. The input terminal is configured to receive an input voltage of a positive polarity or a negative polarity. The output terminal is configured to be coupled to an output voltage of a positive polarity or a negative polarity. The power transistor is configured to provide a current conduction path between the input terminal and the output terminal, and the power transistor has a control electrode. The main control circuit is coupled to the reference terminal and is configured to provide a control signal relative to a voltage level at the reference terminal to the control electrode of the power transistor. The variable resistance circuit is coupled between the reference terminal and the power ground terminal, and is configured to be switched between an ON state and an OFF state based on a driving voltage applied to a control terminal of the variable resistance circuit. The driver circuit is configured to adjust the driving voltage based on the polarity of the input voltage or the polarity of the output voltage. The input capacitor is coupled between the input terminal of the integrated circuit and the power ground terminal of the integrated circuit to receive the input voltage. The output capacitor is coupled between the output terminal of the integrated circuit and the power ground terminal to provide the output voltage.

Yet another embodiment of the present invention discloses a reverse polarity protection circuit. The reverse polarity protection circuit comprises a first transistor and a second transistor and a driver circuit. The first transistor and the second transistor are coupled in parallel between a power ground terminal and a reference terminal. The driver circuit is coupled to an input terminal to receive an input voltage and coupled to an output terminal to receive an output voltage, and configured to respectively provide a first driving voltage to a control electrode of the first transistor and a second driving voltage to a control electrode of the second transistor. When the input voltage at the input terminal relative to a ground signal at the power ground terminal and the output voltage at the output terminal relative to the ground signal at the power ground terminal both have a first polarity, the first driving voltage is configured to turn on the first transistor for providing a first path from the power ground terminal to the reference terminal. The second driving voltage is configured to turn on the second transistor for providing a second path from the power ground terminal to the reference terminal. A first resistance of the first path is smaller than a second resistance of the second path. When the input voltage at the input terminal relative to the ground signal at the power ground terminal and the output voltage at the output terminal relative to the ground signal at the power ground terminal both have a second polarity opposite to the first polarity, the first transistor and the second transistor are turned off.

### BRIEF DESCRIPTION OF DRAWINGS

The present invention can be further understood with reference to the following detailed description and the appended drawings, wherein like elements are provided with like reference numerals.

FIG. 1 shows a schematic circuit diagram of an electronic circuit 100 in accordance with an embodiment of the present invention.

FIG. 2 shows a block circuit diagram of an integrated circuit 10A in accordance with an embodiment of the present invention.

FIG. 3 shows a schematic diagram of a reverse polarity protection circuit 104A in accordance with an embodiment of the present invention.

FIG. 4 shows a schematic diagram of a reverse polarity protection circuit 104B in accordance with an embodiment of the present invention.

FIG. 5 shows a schematic diagram of a reverse polarity protection circuit 104C in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Reference to “one embodiment”, “an embodiment”, “an example” or “examples” means: certain features, structures, or characteristics are contained in at least one embodiment of the present invention. These “one embodiment”, “an embodiment”, “an example” and “examples” are not necessarily directed to the same embodiment or example. Furthermore, the features, structures, or characteristics may be combined in one or more embodiments or examples. In addition, it should be noted that the drawings are provided for illustration, and are not necessarily to scale. And when an element is described as “connected” or “coupled” to another element, it can be directly connected or coupled to the other element, or there could exist one or more intermediate elements. In contrast, when an element is referred to as “directly connected” or “directly coupled” to another element, there is no intermediate element.

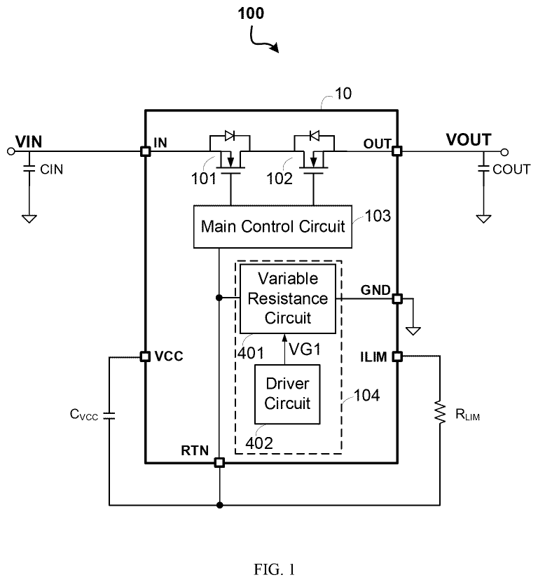

FIG. 1 shows a schematic circuit diagram of an electronic circuit 100 in accordance with an embodiment of the present invention. The electronic circuit 100, e.g., an electronic fuse (eFuse), is configured as a protection device of integrated power path for limiting voltage or current within a regular and safety range. As shown in FIG. 1, the electronic circuit 100 comprises an input capacitor CIN, an output capacitor COUT and an integrated circuit 10. In one embodiment, the integrated circuit 10 has a plurality of terminals. The plurality terminals comprises an input terminal IN, an output terminal OUT, a reference terminal RTN, a power ground terminal GND of the electronic circuit 100 or a system, a power supply terminal VCC and a current limiting terminal ILM.

As used herein, a “terminal” refers to any contact point configured to make an electrical connection. A terminal may be implemented as pin, pad, post, tab, or other conductive feature suitable for electrically coupling to another component or node.

Conventionally, in order to provide reverse polarity protection for internal circuits of the integrated circuit 10, a traditional solution is to externally connect a diode (e.g., a Zener diode) between the reference terminal RTN of the integrated circuit 10 and the power ground terminal GND of the integrated circuit 10. However, such additional discrete components may unnecessarily increase the cost. Furthermore, since the diode for reverse polarity protection is connected in series in the operating voltage path, there is a high voltage difference (e.g., about 1V) between the reference terminal RTN and the power ground terminal GND, which will cause a significant voltage drop and thus a significant power loss. In addition, the voltage drop of the Zener diode is temperature-sensitive, and may change with current or temperature, which also increase the difficulty and complexity of circuit design.

To solve one or more problems mentioned above, the inventor proposes an integrated circuit 10 that incorporates with reverse polarity protection at both input side and output side. As shown in FIG. 1, the integrated circuit 10 comprises a pair of power transistors 101 and 102, a main control circuit 103 and a reverse polarity protection circuit 104.

In the example shown in FIG. 1, the input terminal IN is configured to receive an input voltage VIN from an input power source (e.g., a battery). In real applications, the input voltage VIN may have a normal positive polarity or an abnormal negative polarity. The output terminal OUT is configured to be coupled to an output voltage VOUT for powering a load. The output voltage VOUT may have a normal positive polarity or an abnormal negative polarity. As shown in FIG. 1, the input voltage VIN and the output voltage VOUT both use a ground signal at the power ground terminal GND as a reference level. The input capacitor CIN is coupled between the input terminal IN and the power ground terminal GND. The output capacitor COUT is coupled between the output terminal OUT and the power ground terminal GND.

The power transistors 101 and 102 are coupled in series between the input terminal IN and the output terminal OUT, and provides a current conduction path between the input terminal IN and the output terminal OUT. In an example, a back to back switch may be employed to implement the power transistors 101 and 102. In one example shown in FIG. 1, the back to back switch may comprise a pair of N type field effect transistors. In detail, a source electrode of the power transistor 102 is connected to the output terminal OUT, a drain electrode of the power transistor 102 is connected to a drain electrode of the power transistor 101, a source electrode of the power transistor 101 is connected to the input terminal IN. In one embodiment, the power transistors 101 and 102 can comprise an eFuse switch.

It should be noted that the reference terminal RTN is used to be a dedicated reference terminal of the integrated circuit 10, and serves as a reference of all the internal circuits (e.g., the main control circuit 103 and other logic circuits, internal power supply circuits, etc.) of the integrated circuit 10. As shown in FIG. 1, the power supply terminal VCC of the integrated circuit 10 is coupled to an external power supply capacitor C_{VCC}. The power supply capacitor C_{VCC} is coupled between the power supply terminal VCC and the reference terminal RTN. An external resistor RLIM is coupled to the current limiting terminal ILIM and the reference terminal RTN. The main control circuit 103 is also coupled to the reference terminal RTN, to provide a control signal with reference to (or relative to) a voltage at the reference terminal RTN. The control signal is provided to control electrodes of the power transistors 101 and 102.

Referring still to FIG. 1, the reverse polarity protection circuit 104 may comprise a variable resistance circuit 401 and a driver circuit 402. The variable resistance circuit 401 is coupled between the reference terminal RTN and the power ground terminal GND. The variable resistance circuit 401 is configured to be switched between an ON state and an OFF state based on a driving voltage VG1 applied to a control terminal of the variable resistance circuit. It is noted that the term “ON state” of the variable resistance circuit 401 refers that a current path from the power ground terminal GND to the reference terminal RTN is activated. And the term “OFF state” of the variable resistance circuit 401 refers that the current path from the power ground terminal GND to the reference terminal RTN is forbidden. The driver circuit 402 is configured to adjust the driving voltage VG1 based on the polarity of the input voltage VIN or the polarity of the output voltage VOUT.

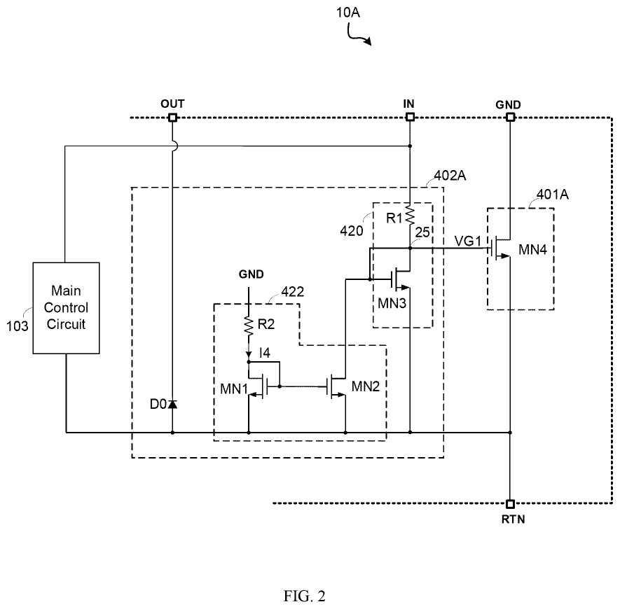

In accordance with an exemplary embodiment, the reverse polarity protection circuit 104 uses the dedicated reference terminal RTN as the reference of the internal circuits of the integrated circuit 10, to implement the reverse polarity protection of the reference terminal RTN relative to the power ground terminal GND. If either the input voltage VIN relative to the power ground terminal GND or the output voltage VOUT relative to the power ground terminal GND has negative polarity, the voltage at the reference terminal RTN of the integrated circuit 10 becomes negative relative to the ground signal, the power transistors 101 and 102 are turned off immediately by the main control circuit 103, to prevent the integrated circuit 10 being destroyed due to the input/output reverse polarity event. Various embodiments of the reverse polarity protection circuit 104 of the present invention are described in detail below with reference to FIGS. 2-4.

FIG. 2 shows a block circuit diagram of an integrated circuit 10A in accordance with an embodiment of the present invention. The integrated circuit 10A can be applied to many different electronic circuits or electronic devices, such as eFuses, linear voltage regulators, etc.

As shown in FIG. 2, the integrated circuit 10A comprises a power transistor (not shown), a main control circuit 103, a variable resistance circuit 401A, a driver circuit 402A and a plurality of terminals. The plurality of terminals comprises an input terminal IN, an output terminal OUT, a reference terminal RTN, a power ground terminal GND. The main control circuit 103 is coupled between the input terminal IN and the reference terminal RTN. The voltage signals involved in the main control circuit 103 use a voltage at the reference terminal RTN as a reference.

The power transistor may be coupled to the reference terminal RTN and is configured to provide the current conduction path between the input terminal IN and the output terminal OUT, and the power transistor has a control electrode. The main control circuit 103 is coupled to the reference terminal RTN and is configured to provide a control signal relative to the voltage at the reference terminal RTN to the control electrode of the power transistor.

In the example shown in FIG. 2, the variable resistance circuit 401A comprises a field effect transistor MN4. The variable resistance circuit 401A is coupled between the power ground terminal GND and the reference terminal RTN. The variable resistance circuit 401A has a control terminal 25. In an example, the transistor MN4 has a source electrode, a drain electrode and a control electrode. The drain electrode of the transistor MN4 is connected to the power ground terminal GND, the source electrode of the transistor MN4 is connected to the reference terminal RTN, the control electrode of the transistor MN4 is connected to receive the driving voltage VG1. Based on the driving voltage VG1, the transistor MN4 is configured to provide a current conduction path from the power ground terminal GND to the reference terminal RTN.

In one embodiment, the driver circuit 402A comprises a bias power supply circuit 420, a diode D0 and a pull-down circuit 422. In response the input voltage VIN of the positive polarity, the bias power supply circuit 420 is configured to provide the driving voltage VG1, and the variable resistance circuit 401A is controlled by the driving voltage VG1 to enter the ON state. In response to the input voltage VIN of the negative polarity, the bias power supply circuit 420 is configured to provide the driving voltage VG1, and the variable resistance circuit 401A is controlled to enter the OFF state.

As shown in FIG. 2, the bias power supply circuit 420 comprises a resistor R1 and a transistor MN3. The resistor R1 is coupled between the input terminal IN and the control terminal 25. The transistor MN3 is coupled between the control terminal 25 and the reference terminal RTN. In detail, the drain electrode and the control electrode of the transistor MN3 are both coupled to the control electrode 25. The source electrode of the transistor MN3 is connected to the reference terminal RTN. In an example, the transistor MN3 has a first turn-on threshold voltage. When the input voltage VIN received at the input terminal IN has the positive polarity and is higher than the first turn-on threshold voltage of the transistor MN3, the transistor MN3 is biased to be turned on, the driving voltage VG1 is pulled up to turn on the transistor MN4 that works as the variable resistance circuit 401A.

In one embodiment, when the input voltage VIN is higher than the first turn-on threshold voltage (e.g., 1V) of the transistor MN3, the transistor MN3 is biased to be tuned on, the transistor MN4 is also biased to be tuned on. Since the transistor MN4 has a very small resistance in the ON state, the voltage at the power ground terminal GND is substantially equal to the voltage at the reference terminal RTN. That is, the voltage difference between the power ground terminal GND and the reference terminal RTN is small and substantially zero. It is to be understood that “substantially” is a term of art and is meant to convey the principle that relationship such simultaneity or perfect synchronization cannot be met with exactness, but only within the tolerances of the technology available to a practitioner of the art under discussion.

Referring still to FIG. 2, when the input voltage VIN at the input terminal IN relative to the power ground terminal GND becomes negative, the transistors MN3 and MN4 are both turned OFF, the electronic connection between the reference terminal RTN and the power ground terminal GND is disconnected.

In the example shown in FIG. 2, a diode D0 has an anode and a cathode. The anode of the diode D0 is coupled to the reference terminal RTN. The cathode of the diode D0 is coupled to the output terminal OUT. The pull-down circuit 422 is configured to provide a pull-down path from the control terminal 25 of variable resistance circuit 401A to the reference terminal RTN in response to the output voltage VOUT of negative polarity. As shown in FIG. 2, the pull-down circuit 422 comprises a resistor R2, a transistor MN1 and a transistor MN2. Both transistors MN1 and MN2 have a source electrode, a drain electrode and a control electrode. The control electrode of the transistor MN1 and the control electrode of the transistor MN2 are coupled to the drain electrode of the transistor MN1. The drain electrode of the transistor MN1 is coupled to the power ground terminal GND through a resistor R2. The source electrode of the transistor MN1 and the source electrode of the transistor MN2 are both coupled to the reference terminal RTN. The drain electrode of the transistor MN2 is coupled to the control terminal 25 of the variable resistance circuit 401A.

Referring still to FIG. 2, when the output voltage VOUT at the output terminal OUT relative to the power ground terminal GND becomes negative, the voltage at the reference terminal RTN is clamped to VOUT+VD0 through the diode D0. Where VD0 is a voltage across the diode D0. In one example, VD0 is about 0.7V. Therefore, when the output voltage VOUT becomes negative, the voltage at the reference terminal RTN also becomes negative. As a result, the transistors MN1 and MN2 of the pull-down circuit 422 are both turned ON, a current I4 shown in FIG. 2 is generated to provide a pull-down path from the control terminal 25 of the variable resistance circuit 401A to the reference terminal RTN. The transistor MN3 is accordingly turned OFF. The driving voltage VG1 decreases rapidly, the transistor MN4 is also turned OFF. That is, the variable resistance circuit 401A enters the OFF state. In addition, when the transistor MN4 is turned OFF, a body diode of the transistor MN4 is configured to implement isolation the power ground terminal GND from the reference terminal RTN.

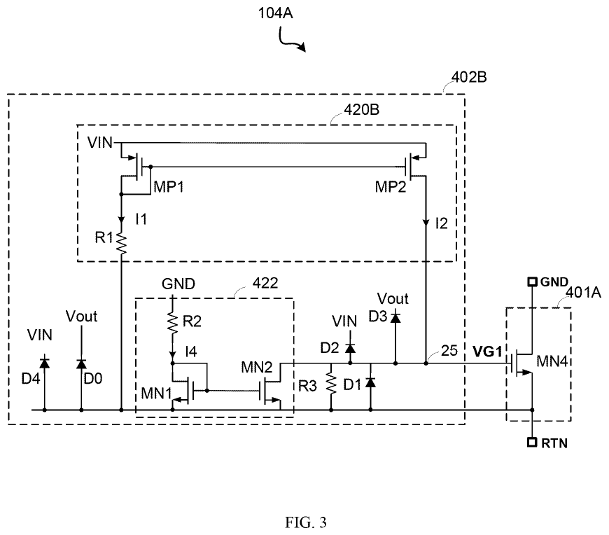

FIG. 3 shows a schematic diagram of a reverse polarity protection circuit 104A in accordance with an embodiment of the present invention. As shown in FIG. 3, the reverse polarity protection circuit 104A comprises a variable resistance circuit 401A and a driver circuit 402B.

In the embodiment shown in FIG. 3, the driver circuit 402B comprises a bias power supply circuit 420B, diodes D0˜D4, and a pull-down circuit 422. As shown in FIG. 3, the bias power supply circuit 420B comprises a resistor R1, a current mirror circuit consisted of two P type transistors MP1 and MP2. The current mirror circuit has a power supply terminal, a current setting terminal and a current output terminal. The power supply terminal of the current mirror circuit is coupled to the input terminal IN to receive the input voltage VIN. The current setting terminal of the current mirror circuit is coupled to the reference terminal RTN. The current output terminal of the current mirror circuit is coupled to the control terminal 25 of the variable resistance circuit 401A. In detail, a source electrode of the transistor MP1 and a source electrode of the transistor MP2 are coupled to the input terminal IN to receive the input voltage VIN. A control electrode of the transistor MP1 and a control electrode of the transistor MP2 are both coupled to a drain electrode of the transistor MP1, the drain electrode of the transistor MP1 is coupled to the reference terminal RTN. A drain electrode of the transistor MP2 is coupled to the control terminal 25 of the variable resistance circuit 401A.

In response to the input voltage VIN of positive polarity, the transistors MP1 and MP2 are turned ON to generate a current I1 and I2 respectively, as shown in FIG. 3. The current I2 flows into the reference terminal RTN through a resistor R3, to provide the appropriate driving voltage VG1, to control the variable resistance circuit 401A to enter the ON state.

Referring still to FIG. 3, the diode D0 has an anode coupled to the reference terminal RTN and a cathode coupled to the output terminal OUT. The diode D1 has an anode coupled to the reference terminal RTN and a cathode coupled to the control terminal 25. The diode D2 has an anode coupled to control terminal 25 and a cathode coupled to the input terminal IN. The diode D3 has an anode coupled to the reference terminal RTN and a cathode coupled to the output terminal OUT. The diode D4 has an anode coupled to the reference terminal RTN and a cathode coupled to the input terminal IN.

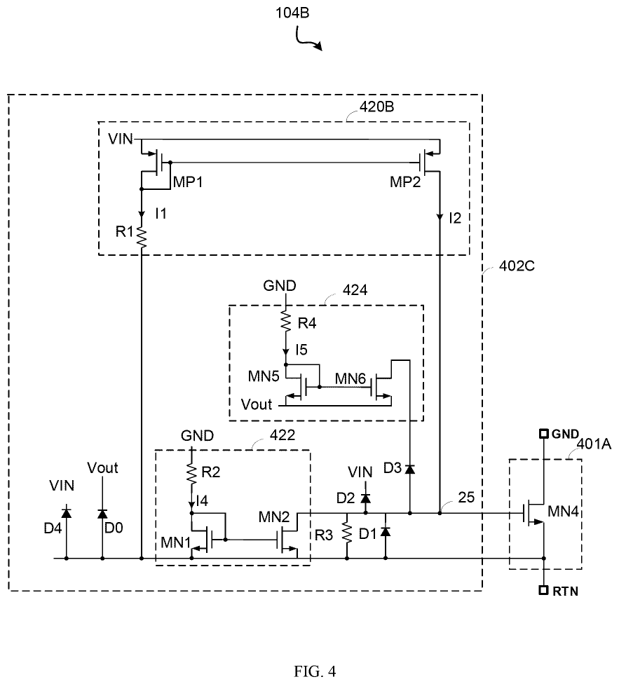

In response to the input voltage VIN of negative polarity, the control terminal 25 discharges through the diode D2, the driving voltage VG1 at the control terminal 25 is pulled down quickly, the variable resistance circuit 401A is controlled to enter the OFF state. At the same time, in response to the input voltage VIN of negative polarity, the diode D4 is forward biased, the voltage at the reference terminal RTN becomes negative. The transistors MN1 and MN2 of the pull-down circuit 422 are tuned ON, a current I4 is generated as shown in FIG. 4, to provide the pull-down path from the control terminal 25 to the reference terminal RTN. The driving voltage VG1 is further pulled down, to ensure the OFF state of the variable resistance circuit 401A.

When the output voltage VOUT at the output terminal OUT relative to the power ground terminal GND becomes negative, the driving voltage VG1 at the control terminal 25 discharges through the diode D3. The voltage at the reference terminal RTN becomes negative through the diode D0, the pull-down circuit 422 generates the current I4 to provide the pull-down path from the control terminal 25 to the reference terminal RTN, to pull down the driving voltage VG1. Thus, the variable resistance circuit 401A is tuned OFF reliably.

FIG. 4 shows a schematic diagram of a reverse polarity protection circuit 104B in accordance with an embodiment of the present invention. Compared with the driver circuit 402B shown in FIG. 3, the driver circuit 402C shown in FIG. 4 further comprises a pull-down circuit 424. The pull-down circuit 424 is configured to provide a pull-down path from the control terminal 25 to the output terminal OUT in response to the output voltage VOUT of negative polarity. In the example shown in FIG. 4, the pull-down circuit 424 comprises a resistor R4, transistors MN5 and MN6. A control electrode of the transistor MN5 and a control electrode of the transistor MN6 are coupled to a drain electrode of the transistor MN5. A source electrode of the transistor MN5 and a source electrode of the transistor MN6 are coupled to the output terminal OUT to receive the output voltage VOUT. The drain electrode of the transistor MN5 is coupled to the control terminal 25 of the variable resistance circuit 401A. In response to the output voltage VOUT of negative polarity, the transistors MN5 and MN6 are turned ON. A current I5 is generated, the driving voltage VG1 at the control terminal 25 is pulled down to the output terminal OUT, to ensure that the variable resistance circuit 401A enters the OFF state reliably.

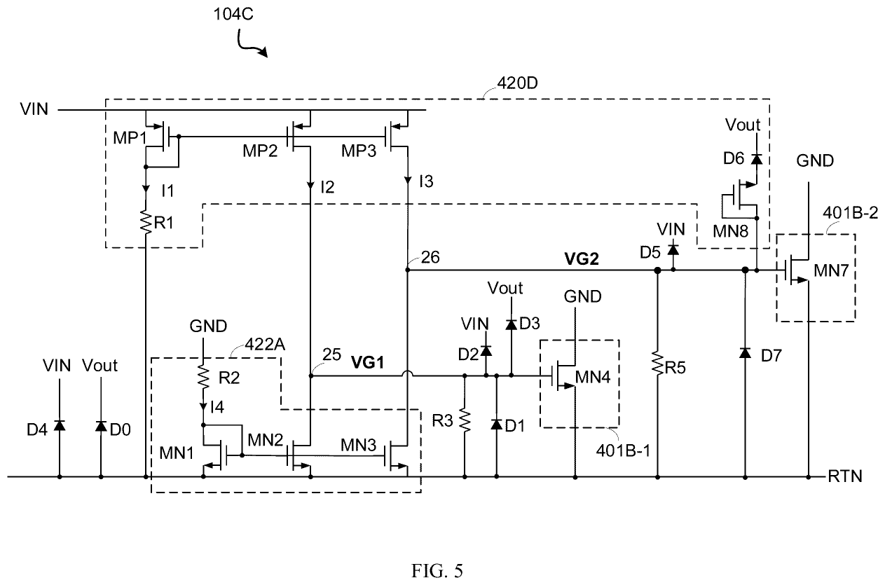

FIG. 5 shows a schematic diagram of a reverse polarity protection circuit 104C in accordance with an embodiment of the present invention. Compared with the reverse polarity protection circuit 104A shown in FIG. 3, the difference is that the reverse polarity protection circuit 104C shown in FIG. 5 comprises a variable resistance circuit 401B, a bias power supply circuit 420D and a pull-down circuit 422A.

As shown in FIG. 5, the variable resistance circuit 401B comprises a first path 401B-1 and a second path 401B-2. The first path 401B-1 is coupled between the power ground terminal GND and the reference terminal RTN and has a first resistance in the ON state. The second path 401B-2 is coupled between the power ground terminal GND and the reference terminal RTN and has a second resistance in the ON state. The first resistance is smaller than the second resistance. In an example, the first resistance is 50 mΩ, the second resistance is 250 mΩ.

In one embodiment, the first path 401B-1 comprises a transistor MN4 coupled between the power ground terminal GND and the reference terminal RTN. A control electrode (label 25 shown in FIG. 5) of the transistor MN4 is configured to receive the driving voltage VG1. The second path 401B-2 comprises a transistor MN7 coupled between the power ground terminal GND and the reference terminal RTN. A control electrode (label 26 shown in FIG. 5) of the transistor MN7 is configured to receive the driving voltage VG2.

The bias power supply circuit 420D is configured to provide a predetermined voltage difference between the driving voltage VG1 supplied to the control terminal 25 of the first path 401B-1 and the driving voltage VG2 supplied to the control terminal 26 of the second path 401B-2, in response to the input voltage of positive polarity.

In the example shown in FIG. 5, the bias power supply circuit 420D comprises a resistor R1, a current mirror circuit consisting of transistors MP1˜MP3, a level-shift transistor MN8 and a diode D6. The current mirror circuit has a power supply terminal, a current setting terminal, a first current output terminal, and a second current output terminal. The power supply terminal of the current mirror circuit is coupled to the input terminal IN to receive the input voltage VIN. The current setting terminal of the current mirror circuit is coupled to the reference terminal RTN through a resistor R1. The first current output terminal of the current mirror circuit is coupled to the control electrode of the transistor MN4. The second current output terminal of the current mirror circuit is coupled to the control electrode of the transistor MN7. The control electrode of the transistor MN4 is coupled to the reference terminal RTN through a resistor R3. The control electrode of the transistor MN7 is coupled to the reference terminal RTN through a resistor R5.

As shown in FIG. 5, the level-shift transistor MN8 is configured to provide a predetermined voltage offset between the driving voltage VG1 and the driving voltage VG2. In one embodiment, a control electrode of the level-shift transistor MN8 and a drain electrode of the level-shift transistor MN8 are coupled to the control electrode 26 of the transistor MN7, a source electrode of the level-shift transistor MN8 is coupled to the output terminal OUT through the diode D6 to receive the output voltage VOUT.

In one embodiment, in response to the input voltage of positive polarity, if the output voltage VOUT has not been established, i.e., the output voltage VOUT is still low, the driving voltage VG1 is clamped to be VD3+VOUT. Where VD3 is a forward-biased voltage drop of the diode D3, is about 0.7V. Therefore, when the output voltage VOUT is low, the driving voltage VG1 is also low. In this way, the transistor MN4 is configured to operate in the linear region, the resistance of the transistor MN4 is higher in the ON state, so the first resistance of the first path 401B is higher in the ON state.

The level-shift transistor MN8 is configured to further shift the driving voltage VG1 with the pre-determined voltage drop VMN8, and to provide the driving voltage VG2 of about VD6+VMN8+VOUT. In other words, the driving voltage VG2 is higher than the driving voltage VG1, and the voltage difference between the driving voltage VG2 and the driving voltage VG1 is the voltage drop VMN8. In one embodiment, the VMN8 is about 0.7V, and is configured by a turn-on threshold voltage of the level-shift transistor MN8. In one example, in response to the input voltage of positive polarity, the transistor MN7 is fully turned on first. Subsequently, when the input voltage VIN and the output voltage VOUT are both higher than a threshold voltage (e.g., 4V), the transistor MN4 and MN7 are fully turned ON. At this time, the first resistance of the first path 401B-1 is smaller than the second resistance of the second path 401B-2 in the ON state.

In one embodiment, when the input voltage VIN at the input terminal IN relative to the power ground terminal GND becomes negative, the driving voltage VG1 discharges through the diode D2, and the driving voltage VG2 discharges through a diode D5, the transistors MN4 and MN7 are turned OFF. The voltage at the reference terminal RTN becomes negative through the diode D4. The pull-down circuit 422A is configured to generate the current I4 through the transistor MN1, the transistor MN2 is turned ON to provide a first pull-down path from the control terminal 25 of the transistor MN4 to the reference terminal RTN, the transistor MN3 is turned ON to provide a second pull-down path from the control terminal 26 of the transistor MN7 to the reference terminal RTN.

In one embodiment, when the output voltage VOUT at the output terminal OUT relative to the power ground terminal GND becomes negative, the driving voltage VG1 discharges through the diode D3, and the driving voltage VG2 discharges through the diode D6 and the level-shift transistor MN8. Since the driving voltage VG1 is smaller than the driving voltage VG2, the transistor MN4 is turned OFF first. Subsequently, the voltage of the reference terminal RTN becomes negative due to the forward-biased diode D0. The pull-down circuit 422A is configured to generate the current I4 through the resistor R2 and the transistor MN1, to further pull down the drive voltages (VG1 and VG2) to the reference terminal RTN, and the transistor MN7 is turned OFF, the variable resistance circuit 401b enters the OFF state reliably.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language.

Obviously, many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated, and they obviously will be resorted to by those skilled in the art without departing from the spirit and the scope of the invention as hereinafter defined by the appended claims as only a preferred embodiment(s) thereof has been disclosed.

What is claimed is:

1. An integrated circuit, comprising:
an input terminal configured to receive an input voltage of a positive polarity or a negative polarity;
an output terminal configured to be coupled to an output voltage of a positive polarity or a negative polarity;
a reference terminal;
a power ground terminal;
a power transistor configured to provide a current conduction path between the input terminal and the output terminal, and the power transistor has a control electrode;
a main control circuit coupled to the reference terminal and configured to provide a control signal relative to a voltage level at the reference terminal to the control electrode of the power transistor;
a variable resistance circuit coupled between the reference terminal and the power ground terminal, and configured to be switched between an ON state and an OFF state based on a driving voltage applied to a control terminal of the variable resistance circuit; and
a driver circuit configured to adjust the driving voltage based on the polarity of the input voltage or the polarity of the output voltage.

2. The integrated circuit of claim 1, wherein the driver circuit comprises:
a bias power supply circuit configured to engage the variable resistance circuit to enter the ON state in response to the input voltage of the positive polarity and to engage the variable resistance circuit to enter the OFF state in response to the input voltage of the negative polarity;
a first diode having an anode coupled to the reference terminal and a cathode coupled to the output terminal; and
a first pull-down circuit configured to provide a first pull-down path from the control terminal of the variable resistance circuit to the reference terminal in response to the output voltage of the negative polarity.

3. The integrated circuit of claim 2, wherein the driver circuit further comprise:
a second diode having an anode coupled to the reference terminal and a cathode coupled to the control terminal of the variable resistance circuit;
a third diode having an anode coupled to the control terminal of the variable resistance circuit and a cathode coupled to the input terminal;
a fourth diode having an anode coupled to the control terminal of the variable resistance circuit and a cathode coupled to the output terminal; and
a fifth diode having an anode coupled to the reference terminal and a cathode coupled to the input terminal.

4. The integrated circuit of claim 2, wherein the driver circuit further comprises:
a second pull-down circuit configured to provide a second pull-down path from the control terminal of the variable resistance circuit to the output terminal in response to the output voltage of the negative polarity.

5. The integrated circuit of claim 1, wherein the variable resistance circuit comprises:
a first path coupled between the power ground terminal and the reference terminal and having a first resistance in the ON state; and
a second path coupled between the power ground terminal and the reference terminal and having a second resistance in the ON state, and wherein the first resistance is smaller than the second resistance.

6. The integrated circuit of claim 5, wherein the driver circuit comprises:
a bias power supply circuit configured to provide a predetermined voltage difference between a first driving voltage applied to a control terminal of the first path and a second driving voltage applied to a control terminal of the second path in response to the input voltage of the positive polarity;
a first diode having a cathode coupled to the input terminal and an anode coupled to the reference terminal;
a second diode having a cathode coupled to the output terminal and an anode coupled to the reference terminal; and
a first pull-down circuit configured to respectively provide a first pull-down path from the control terminal of the first path to the reference terminal and a second pull-down path from the control terminal of the second path to the reference terminal in response to the output voltage of the negative polarity.

7. The integrated circuit of claim 1, wherein the variable resistance circuit at least comprises a field effect transistor.

8. The integrated circuit of claim 1, wherein the power transistor comprises a back to back switch.

9. An electronic circuit, comprising:
an integrated circuit, comprising:
an input terminal configured to receive an input voltage of a positive polarity or a negative polarity;
an output terminal configured to be coupled to an output voltage of a positive polarity or a negative polarity;
a reference terminal;
a power ground terminal;
a power transistor configured to provide a current conduction path between the input terminal and the output terminal, and the power transistor has a control electrode;
a main control circuit coupled to the reference terminal and configured to provide a control signal relative to a voltage level at the reference terminal to the control electrode of the power transistor;
a variable resistance circuit coupled between the reference terminal and the power ground terminal, and configured to be switched between an ON state and an OFF state based on a driving voltage applied to a control terminal of the variable resistance circuit; and
a driver circuit configured to adjust the driving voltage based on the polarity of the input voltage or the polarity of the output voltage;
an input capacitor coupled between the input terminal of the integrated circuit and the power ground terminal of the integrated circuit to receive the input voltage; and
an output capacitor coupled between the output terminal of the integrated circuit and the power ground terminal to provide the output voltage.

10. The electronic circuit of claim 9, wherein the driver circuit comprises:
a bias power supply circuit configured to engage the variable resistance circuit to enter the ON state in response to the input voltage of the positive polarity and to engage the variable resistance circuit to enter the OFF state in response to the input voltage of the negative polarity;
a first diode having an anode coupled to the reference terminal and a cathode coupled to the output terminal; and
a first pull-down circuit configured to provide a first pull-down path from the control terminal of the variable resistance circuit to the reference terminal in response to the output voltage of the negative polarity.

11. The electronic circuit of claim 10, wherein the driver circuit comprises:
a second diode having an anode coupled to the reference terminal and a cathode coupled to the control terminal of the variable resistance circuit;
a third diode having an anode coupled to the control terminal of the variable resistance circuit and a cathode coupled to the input terminal;
a fourth diode having an anode coupled to the control terminal of the variable resistance circuit and a cathode coupled to the output terminal; and
a fifth diode having an anode coupled to the reference terminal and a cathode coupled to the input terminal.

12. The electronic circuit of claim 10, wherein the driver circuit further comprises:
a second pull-down circuit configured to provide a second pull-down path from the control terminal of the variable resistance circuit to the output terminal in response to the output voltage of the negative polarity.

13. The electronic circuit of claim 9, wherein the variable resistance circuit comprises:
a first path coupled between the power ground terminal and the reference terminal and having a first resistance in the ON state; and
a second path coupled between the power ground terminal and the reference terminal and having a second resistance in the ON state, and wherein the first resistance is smaller than the second resistance.

14. The electronic circuit of claim 13, wherein the driver circuit comprises:
a bias power supply circuit configured to provide a predetermined voltage difference between a first driving voltage applied to a control terminal of the first path and a second driving voltage applied to a control terminal of the second path in response to the input voltage of the positive polarity;
a first diode having a cathode coupled to the input terminal and an anode coupled to the reference terminal;
a second diode having a cathode coupled to the output terminal and an anode coupled to the reference terminal; and
a first pull-down circuit configured to respectively provide a first pull-down path from the control terminal of the first path to the reference terminal and a second pull-down path from the control terminal of the second path to the reference terminal in response to the output voltage of the negative polarity.

15. The electronic circuit of claim 9, wherein the variable resistance circuit at least comprises a field effect transistor.

16. A reverse polarity protection circuit, comprising:
a first transistor and a second transistor, coupled in parallel between a power ground terminal and a reference terminal;
a driver circuit coupled to an input terminal to receive an input voltage and coupled to an output terminal to receive an output voltage, and configured to respectively provide a first driving voltage to a control electrode of the first transistor and a second driving voltage to a control electrode of the second transistor; and
wherein when the input voltage at the input terminal relative to a ground signal at the power ground terminal and the output voltage at the output terminal relative to the ground signal at the power ground terminal both have a first polarity, the first driving voltage is configured to turn on the first transistor for providing a first path from the power ground terminal to the reference terminal, the second driving voltage is configured to turn on the second transistor for providing a second path from the power ground terminal to the reference terminal, and a first resistance of the first path is smaller than a second resistance of the second path; and
when the input voltage at the input terminal relative to the ground signal at the power ground terminal and the output voltage at the output terminal relative to the ground signal at the power ground terminal both have a second polarity opposite to the first polarity, the first transistor and the second transistor are turned off.

17. The reverse polarity protection circuit of claim 16, wherein the driver circuit comprises:
a current mirror circuit having a power supply terminal, a current setting terminal, a first current output terminal and a second current output terminal, wherein the power supply terminal is coupled to the input terminal, the current setting terminal is coupled to the reference terminal through a first resistor, the first current output terminal is coupled to the control electrode of the first transistor, and the second current output terminal is coupled to the control electrode of the second transistor;
a level-shift transistor configured to provide a predetermined voltage difference between the first driving voltage and the second driving voltage;
a first diode having an anode coupled to the input terminal and a cathode coupled to the reference terminal;
a second diode having an anode coupled to the output terminal and a cathode coupled to the reference terminal; and
a pull-down circuit configured to respectively provide a first pull-down path from the control electrode of the first transistor to the reference terminal and a second pull-down path from the control electrode of the second transistor to the reference terminal in response to the input voltage of the second polarity or the output voltage of the second polarity.

18. The reverse polarity protection circuit of claim 17, wherein the driver circuit further comprises:
a third diode having an anode coupled to the reference terminal and a cathode coupled to the control electrode of the first transistor;
a fourth diode having an anode coupled to the control electrode of the first transistor and a cathode coupled to the input terminal;
a fifth diode having an anode coupled to the control electrode of the first transistor and a cathode coupled to the output terminal;
a sixth diode having an anode coupled to the reference terminal and a cathode coupled to the control electrode of the second transistor;
a seventh diode having an anode coupled to the control electrode of the second transistor and a cathode coupled to the input terminal; and
an eighth diode having an anode coupled to the control electrode of the second transistor through a level-shift transistor and a cathode coupled to the output terminal.

19. The reverse polarity protection circuit of claim 16, wherein in response to the input voltage of the first polarity, the first transistor is fully turned on first, and the second transistor is fully turned on later.

20. The reverse polarity protection circuit of claim 16, wherein in response to the output voltage of the second polarity, the first transistor is turned off first, the second transistor is turned off later.
